(19) United States
(12) Patent Application Publication
(10) Pub. No.: US 2024/0332009 A1
(43) Pub. Date: Oct. 3, 2024

(54) ION IMPLANTATION FOR REDUCED ROUGHNESS OF SILICON NITRIDE

(71) Applicant: Applied Materials, Inc., Santa Clara, CA (US)

(72) Inventors: Qixin Shen, San Jose, CA (US); Chuanxi Yang, Los Altos, CA (US); Hang Yu, San Jose, CA (US); Deenesh Padhi, Saratoga, CA (US); Prashanthi Para, Santa Clara, CA (US); Miguel S. Fung, Cupertino, CA (US); Rajesh Prasad, Lexington, MA (US); Fenglin Wang, Lexington, MA (US); Shan Tang, Middleton, MA (US); Kyu-Ha Shim, Andover, MA (US)

(73) Assignee: Applied Materials, Inc., Santa Clara, CA (US)

(21) Appl. No.: 18/616,689

(22) Filed: Mar. 26, 2024

Related U.S. Application Data
(60) Provisional application No. 63/456,093, filed on Mar. 31, 2023.

(51) Int. Cl. H01L 21/02; H01L 21/67

(52) U.S. Cl. CPC H01L 21/02321; H01L 21/0217; H01L 21/02274; H01L 21/67213

(57) ABSTRACT

Exemplary methods of semiconductor processing may include forming a layer of silicon nitride on a semiconductor substrate. The layer of silicon nitride may be characterized by a first roughness. The methods may include performing a post-deposition treatment on the layer of silicon nitride. The methods may include reducing a roughness of the layer of silicon nitride such that the layer of silicon nitride may be characterized by a second roughness less than the first roughness.

### CROSS-REFERENCE TO RELATED APPLICATIONS

This application claims the benefit of, and priority to U.S. Provisional Application Ser. No. 63/456,093, filed Mar. 31, 2023, which is hereby incorporated by reference in its entirety for all purposes.

### TECHNICAL FIELD

The present technology relates to methods and systems for semiconductor processing. More specifically, the present technology relates to systems and methods for producing films with reduced roughness.

### BACKGROUND

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. Materials used to form layers of materials may affect operational characteristics of the devices produced. As material thicknesses continue to reduce, as-deposited characteristics of the films may have a greater impact on device performance.

Thus, there is a need for improved systems and methods that can be used to produce high quality devices and structures. These and other needs are addressed by the present technology.

### SUMMARY

Exemplary methods of semiconductor processing may include forming a layer of silicon nitride on a semiconductor substrate. The layer of silicon nitride may be characterized by a first roughness. The methods may include performing a post-deposition treatment on the layer of silicon nitride. The methods may include reducing a roughness of the layer of silicon nitride such that the layer of silicon nitride may be characterized by a second roughness less than the first roughness.

In some embodiments, the semiconductor substrate may be maintained at a temperature below or about 550° C. during the semiconductor processing method. The post-deposition treatment may include an ion implantation process. The ion implantation process may be performed at a temperature of greater than or about −100° C. The ion implantation process may be performed with helium, neon, argon, silicon, boron, carbon, nitrogen, or germanium ions. The post-deposition treatment may include a beamline ion implantation process or a plasma doping process. The first roughness may be greater than or about 0.50 nm. The second roughness may be less than or about 0.30 nm.

Some embodiments of the present technology encompass semiconductor processing methods. The methods may include forming a layer of silicon nitride on a semiconductor substrate. The layer of silicon nitride may be characterized by a first roughness. The methods may include transferring the semiconductor substrate to a beamline ion implantation chamber or plasma doping chamber. The methods may include performing a beamline ion implantation process or a plasma doping process on the layer of silicon nitride. The methods may include reducing a surface roughness of the layer of silicon nitride to a second roughness less than the first roughness.

In some embodiments, the layer of silicon nitride may be formed on a layer of polysilicon. The layer of silicon nitride may be formed through plasma-enhanced chemical vapor deposition. The layer of silicon nitride may be characterized by a thickness of less than or about 100 nm. The layer of silicon nitride may be formed at a temperature of less than or about 500° C. The beamline ion implantation process or the plasma doping process is performed at a temperature of less than or about 550° C. The beamline ion implantation process or the plasma doping process may be performed at a temperature of greater than or about −100° C. The beamline ion implantation process or the plasma doping process is performed at a temperature of less than or about 50° C. The beamline ion implantation process or the plasma doping process may be performed with helium, neon, argon, silicon, boron, nitrogen, or carbon ions. The second roughness may be less than or about 0.40 nm.

Some embodiments of the present technology encompass semiconductor processing methods. The methods may include forming a layer of silicon nitride on a semiconductor substrate within a first semiconductor processing chamber. The layer of silicon nitride may be characterized by a first roughness. Tayer of silicon nitride is formed on a layer of material. The methods may include transferring the semiconductor substrate from the first semiconductor processing chamber to an ion implantation chamber. The methods may include performing an ion implantation process on the layer of silicon nitride. The ion implantation process may be or include a beamline ion implantation process or a plasma doping process. The methods may include reducing a surface roughness of the layer of silicon nitride to a second roughness less than the first roughness.

In some embodiments, the layer of material may be or include polysilicon. The layer of silicon nitride may be formed at a temperature of less than or about 550° C. The ion implantation process may be performed at a temperature of greater than or about −100° C. The first roughness may be at least about 0.60 nm. The second roughness may be less than or about 0.50 nm.

Such technology may provide numerous benefits over conventional systems and techniques. For example, embodiments of the present technology may produce films characterized by reduced roughness. Additionally, the present technology may reduce grain size in the film. The reduced roughness and/or reduced grain size in the film may reduce line width roughness in subsequently formed materials overlying films characterized by reduced roughness/grain size. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma deposition system according to some embodiments of the present technology.

FIG. 3 shows operations in a semiconductor processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor device sizes continue to reduce, the constituent films included within a structure may affect device performance, as well as fabrication of other materials being included in the device. Additionally, as demand increases, throughput and queue times become a point of emphasis. Thus, a demand exists for high-quality materials and structures that may be formed both quickly and efficiently. However, in processes to form silicon nitride materials, quicker processes, such as chemical vapor deposition or plasma-enhanced chemical vapor deposition, may result in materials with increased surface roughness. Due to the rapid deposition of material, grain size in the films may increase. Grain size may affect film properties, which can cause uneven film surfaces that propagate to subsequent materials deposited on the silicon nitride.

To reduce grain size in the films, conventional technologies may change deposition parameters and may perform an atomic layer deposition. For example, when deposition is performed on an atomic layer basis, grain size in the films may be maintained at a certain level, which may improve film quality and characteristics. Although these techniques may be effective, atomic layer deposition reduces throughput.

A correlation may exist between grain size in silicon nitride films and surface roughness. For example, increased grain size, which may more readily occur during chemical vapor deposition and plasma-enhanced chemical vapor deposition as opposed to atomic layer deposition, may cause an increased surface roughness. Further, a correlation may exist between surface roughness in silicon nitride films and line width roughness of subsequent materials deposited or formed on the silicon nitride films. For example, increased surface roughness may cause an increased line width roughness in materials deposited on the silicon nitride films. The increased line width roughness may cause nonuniformity in final devices. Consequently, by reducing surface roughness in silicon nitride films, film and/or device performance may increase over conventional structures.

The present technology overcomes these issues by performing an ion implantation process to reorganize constituent bonds and reduce grain size in the films. By implanting ions with sufficient energy, grain sizes may be reduced and, therefore, surface roughness may be reduced. Additionally, by utilizing particular ion implantation techniques, or by adjusting ion dosing, substrate temperature during implant, sputtering, and material affects may be limited.

Although the remaining disclosure will routinely identify specific deposition processes utilizing the disclosed technology, it will be readily understood that the systems and methods are equally applicable to other deposition and etch processes as may occur in the described chambers or any other chamber. Accordingly, the technology should not be considered to be so limited as for use with these specific deposition processes or chambers alone. The disclosure will discuss one set of possible chambers that may be used to perform processes according to embodiments of the present technology before additional variations and adjustments to this system according to embodiments of the present technology are described.

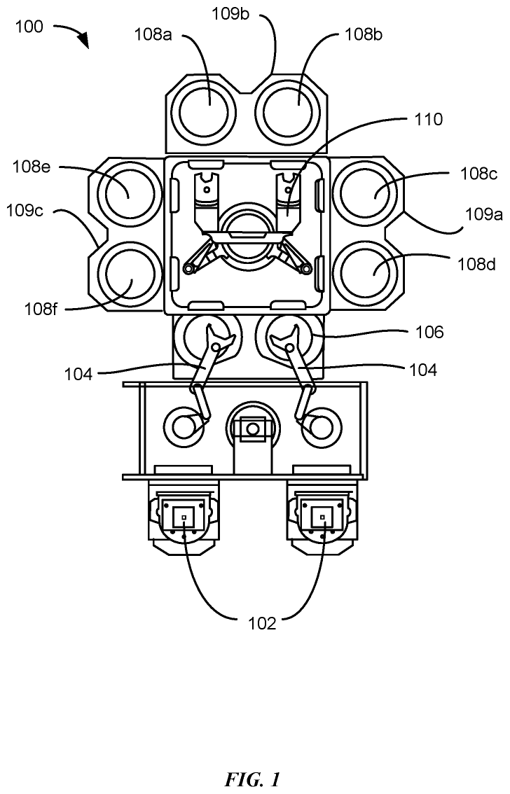

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

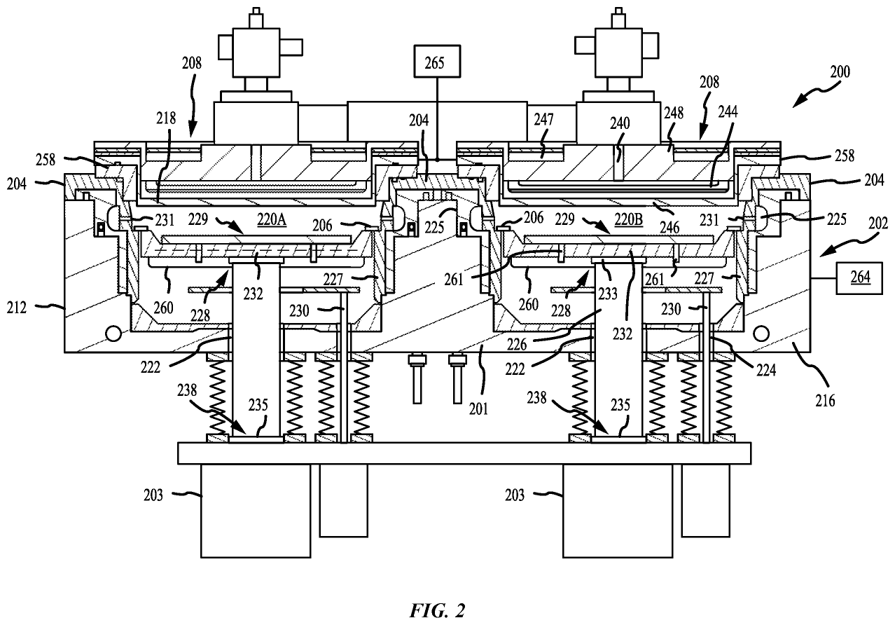

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

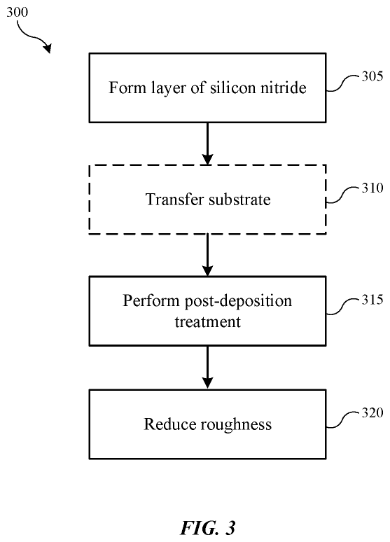

FIG. 3 shows exemplary operations in a processing method 300 according to some embodiments of the present technology. The method may be performed in a variety of processing chambers, including processing chamber 200 described above. Method 300 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

Method 300 may involve optional operations to develop the semiconductor structure to a particular fabrication operation. Although in some embodiments method 300 may be performed on a base structure, in some embodiments the method may be performed subsequent other material formation or removal. For example, any number of deposition, masking, or removal operations may be performed to produce any transistor, memory, or other structural aspects on a substrate. The substrate may be disposed on a substrate support, which may be positioned within a processing region of a semiconductor processing chamber. The operations may be performed in the same chamber in which aspects of method 300 may be performed, and one or more operations may also be performed in one or more chambers on a similar platform as a chamber in which operations of method 300 may be performed, or on other platforms.

In some embodiments, method 300 may include forming a layer of silicon nitride on a substrate at operation 305. The formation or deposition may be performed using any number of precursors, such as silane or other silicon-containing materials, and in some embodiments a silicon-containing precursor delivered may also include hydrogen or nitrogen. The precursors may also include diatomic nitrogen, ammonia, or other nitrogen-containing materials, diatomic hydrogen or other hydrogen-containing materials, or any other precursors to form a silicon nitride material including carrier gases as well as inert materials. Consequently, the deposited or formed layer of silicon nitride may be characterized by a first roughness. It is to be understood that the present technology may not be limited to silicon films, such as silicon nitride. The present technology may also encompass roughness management in any number of films formed on semiconductor substrates. Consequently, the silicon nitride material should be considered as only one example film for which the present technology may apply.

The layer of silicon nitride may be part of any number of structures, which may include thin-film transistor structures in some embodiments. For example, in some embodiments the layer of silicon nitride may be one of multiple layers in a stack of films formed over a substrate. In some embodiments the layer of silicon nitride may be included above another layer of material or between other layers of material, such as other silicon-containing materials or other material layers. In some structures, the layer of silicon nitride material may be formed on a layer of material, such as a polysilicon material. In some structures, the layer of silicon nitride may be formed between layers of polysilicon material. Each layer of the stack, including the layer of silicon nitride material may be characterized by a film thickness of less than or about 500 nm, and may be characterized by a film thickness of less than or about 400 nm, less than or about 350 nm, less than or about 300 nm, less than or about 250 nm, less than or about 200 nm, less than or about 150 nm, less than or about 100 nm, less than or about 50 nm, or less.

As noted previously, some embodiments of the present technology may encompass films formed over materials or structures. The underlying materials or structures may be characterized by a thermal budget less than or about 550° C., less than or about 500° C., less than or about 450° C., less than or about 400° C., less than or about 350° C., less than or about 300° C., or less. Accordingly, the layer of silicon nitride may be formed at or below any of these temperatures in some embodiments to accommodate the underlying materials, and in some embodiments one or more operations, including all operations of method 300, may be performed at or below any of these temperatures, and a substrate being processed may be maintained below or about any of these temperatures throughout processing. Processing pressures during formation may be greater than or about 1 Torr in some embodiments, and may be between about 2 Torr and about 20 Torr, between about 2 Torr and about 10 Torr, or between about 2 Torr and about 5 Torr.

In embodiments, the layer of silicon nitride may be formed through plasma-enhanced chemical vapor deposition. During deposition, a plasma of the precursors may be generated at a plasma power of greater than or about 250 W, and may be greater than or about 400 W, greater than or about 500 W, or more. The plasma power may be less than or about 2,500 W, and may be less than or about 2,000 W, less than or about 1,750 W, less than or about 1,500 W, or less. Compared to alternative deposition methods, such as atomic layer deposition, the deposited material may be characterized by an increased grain size and/or roughness. For example, the formed layer may be characterized by a first roughness. Because alternative deposition methods, including atomic layer deposition, may reduce throughput, the first roughness may be greater than or about 0.40 nm, and may be greater than or about 0.45 nm, greater than or about 0.50 nm, greater than or about 0.55 nm, greater than or about 0.60 nm, or more. This surface roughness may cause any of the challenges described previously, including line width roughness issues during subsequent etching operations.

Subsequent film formation, in some embodiments the substrate on which the layer of silicon nitride was formed may be transferred from a first processing chamber to a second processing chamber at optional operation 310. For example, formation or deposition of the silicon nitride layer may be performed in a first chamber, such as chamber 200 or any other deposition chamber in which a silicon-containing material may be deposited. Subsequent deposition, the substrate may be moved to a second chamber for an ion implantation process. The second chamber may be included on the same platform or tool as the first chamber, although in some embodiments the substrate may be moved between tools for an ion implantation process. In embodiments, the second chamber for the ion implantation process may be from the Trident platform (e.g., Trident CRION, Trident Thermion, Trident, etc.) or a plasma doping (PLAD) tool (e.g., PLAD HVMS, PLAD HVM, etc.) available from Applied Materials, Inc. (Santa Clara, Calif.).

At operation 315, a post-deposition treatment, including an ion implantation process, such as beamline ion implantation, may be performed on one or more layers of the substrate, including the silicon nitride layer. Additionally or alternatively, a plasma doping process may be performed at operation 315. Although termed an ion implantation, the process may involve an ion modification in which ion implantation is performed to reorganize the formed film and release materials from the film, and which may include also releasing ions of the ion implantation process. The process may include a beamline ion implantation process, a plasma doping implantation process, or any other implantation as noted previously. The ion implantation process may be performed to modify characteristics of the film. For example, in some embodiments the ion implantation may be performed to reorganize bonds or structure, such as grain sizes, within the material to make the film more amorphous. With reduced grain size and a more amorphous film, surface roughness of the material may decrease. Further, in embodiments, the post-deposition treatment may densify the film and/or increase sp³ formation within the film.

The ion implantation process may be performed at low pressure, depending on the process performed. For example, plasma doping ion implantation may be performed at chamber pressures less than or about 100 mTorr, less than or about 10 mTorr, less than or about 1 mTorr, or less. Beamline ion implantation may be performed at much lower pressures, such as less than or about 0.1 mTorr, less than or about 0.05 mTorr, less than or about 0.01 mTorr, or less. These low pressure operations may facilitate transmission of ions through the film structure. Ion implantation processes may be performed at a variety of substrate temperatures, such as from about −150° C. up to or about 550° C. Exemplary beamline ion implantation species may include inert materials, such as helium, neon, or argon, which will not bond with silicon nitride. Additionally, silicon and/or carbon species may be used and may bond with silicon nitride without doping the material rendering the material n or p-type. An energy range for ion implantation may depend on the species used. For example, for relatively lighter species, such as helium, the energy range may be lower than for heavier species, such as silicon. For light to heavy species, the implant energy range may be from about 200 eV to 300 keV, with an implant dose in the range of from about 1e¹⁴ to 1e¹⁷ ions/cm². For example, helium dosed at an energy of about 300 keV may modify up to 2 μm or more of silicon nitride, while a silicon species may modify less than 1 μm.

The temperature at which the post-deposition treatment may be performed may affect the energy of the ions, and in some embodiments a hot ion implantation may be performed. For example, in some embodiments sufficient reorganization may occur at temperatures above or about −100° C., and may occur at temperatures greater than or about −50° C., greater than or about 0° C., greater than or about 50° C., greater than or about 100° C., greater than or about 150° C., greater than or about 200° C., greater than or about 250° C., greater than or about 300° C., greater than or about 350° C., greater than or about 400° C., greater than or about 450° C., or higher, although in some embodiments the ion implantation process may be performed at less than or about any of the thermal budget temperatures described previously. In additional embodiments, a cold ion implant may be performed at temperatures less than or about 50° C., and may occur at temperatures less than or about 25° C., less than or about 0° C., less than or about −25° C., less than or about −50° C., less than or about −75° C., less than or about −100° C., or less. If plasma doping is performed, a doping bias voltage may range from about 500 V to 10 kV or more. By increasing the bias voltage, thicker films may be modified. As one non-limiting example, bias voltage closer to 10 kV may modify films characterized by a thickness of 50 nm to 200 nm using lighter species, such as helium. The plasma doping may be performed in a range of from 1e¹⁵ to 1e¹⁷ ions/cm². Plasma doping may also be performed in a temperature range of from about 25° C. to about 500° C.

The ion implantation may use ions produced from any number of precursors. For example, in some embodiments ion implantation may be performed with helium, which as a relatively light ion may easily extend through a structure of over 100 nm or more, which may allow reorganization and amorphization at further depths within the film. Helium ion implantation may be performed at higher powers, which may facilitate bond breaking within the film to allow grain size to be reduced. Helium may have a tendency to be trapped within the films when ion implantation may be performed, and thus to facilitate release of helium, ion implantation may be performed at temperatures above or about 250° C., greater than or about 300° C., or higher. In some embodiments, silicon ions may be used in the ion implantation process from any number of silicon-containing precursors. Silicon may be characterized by a heavier mass, which may facilitate bond breaking in some embodiments. Consequently, lower temperature, higher implant energy processes may be performed with silicon. Similarly, because the films being modified may be silicon nitride, silicon ions may not operate as a dopant to the film, and entrapment or incorporation may not detrimentally affect the film produced. Additionally, controlling an implant depth may be easier with heavier ions, and thus improved control over the depth of implant and modification may be provided. For example, the process may be controlled to affect one or more layers of a thin film transistor structure, but may be limited from more than minimal penetration into underlying structures. Additional ions used during the post-deposition treatment may include argon ions and neon ions, which may act similar to helium. Further, boron ions, carbon ions, nitrogen ions, or germanium ions may be used during the post-deposition treatment. Unlike silicon, carbon, or germanium ions, the boron ions may operate as a dopant to the film, and entrapment or incorporation may alter the film produced.

An amount of densification may occur of the films based on reorganization of grain size and reformation of bonds through the film. Accordingly, in some embodiments a thickness of the film after a post-deposition treatment may be less than or about 99% a thickness of the layer or film as-deposited. In some embodiments the thickness may be less than or about 98% a thickness of the as-deposited film, and may be less than or about 97%, less than or about 96%, less than or about 95%, less than or about 94%, less than or about 93%, less than or about 92%, less than or about 91%, less than or about 90%, or less, although a thickness of the layer subsequent ion modification may be maintained at greater than or about 80%, greater than or about 85%, greater than or about 87%, greater than or about 90%, greater than or about 92%, greater than or about 95%, or more.

In addition to the densification causing a change in thickness, in some embodiments a density of the film after a post-deposition treatment may be less than or about 99% a density of the layer or film as-deposited. In some embodiments the density may be less than or about 98% a density of the as-deposited film, and may be less than or about 97%, less than or about 96%, less than or about 95%, or less, although a density of the layer subsequent ion modification may be maintained at greater than or about 80%, greater than or about 85%, greater than or about 87%, greater than or about 90%, greater than or about 92%, greater than or about 95%, or more. In embodiments, the density of the film may be less than or about 2.80 g/cm³, and may be less than or about 2.78 g/cm³, less than or about 2.76 g/cm³, less than or about 2.74 g/cm³, less than or about 2.72 g/cm³, less than or about 2.70 g/cm³, or less.

Sputtering may be limited of the film formed as dosing of ion implantation may be controlled relative to other plasma-enhanced processes. For example, in some embodiments, the dosage of ions may be greater than or about 1e¹⁵ ions/cm², and may be greater than or about 5e¹⁵ ions/cm², greater than or about 1e¹⁶ ions/cm², greater than or about 1e¹⁷ ions/cm², greater than or about 1e¹⁸ ions/cm², or more. Plasma doping implantation may be characterized by higher dosing than beamline implantation, which may facilitate use with helium to break bonds and modify grain size in the film. As the post-deposition treatment is performed, the method 300 may include reducing a roughness of the layer of silicon nitride at operation 320. The roughness of the layer of silicon nitride may be reduced such that the layer of silicon nitride may be characterized by a second roughness less than the first roughness. In embodiments, the second roughness may be less than or about 0.55 nm, and may be less than or about 0.50 nm, less than or about 0.45 nm, less than or about 0.40 nm, less than or about 0.35 nm, less than or about 0.30 nm, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a layer of silicon nitride on a semiconductor substrate, wherein the layer of silicon nitride is characterized by a first roughness;
performing a post-deposition treatment on the layer of silicon nitride; and
reducing a roughness of the layer of silicon nitride such that the layer of silicon nitride is characterized by a second roughness less than the first roughness.

2. The semiconductor processing method of claim 1, wherein the semiconductor substrate is maintained at a temperature below or about 550° C. during the semiconductor processing method.

3. The semiconductor processing method of claim 1, wherein:
the post-deposition treatment comprises an ion implantation process; and
the ion implantation process is performed at a temperature of greater than or about −100° C.

4. The semiconductor processing method of claim 3, wherein the ion implantation process is performed with helium, neon, argon, silicon, boron, carbon, nitrogen, or germanium ions.

5. The semiconductor processing method of claim 1, wherein the post-deposition treatment comprises a beamline ion implantation process or a plasma doping process.

6. The semiconductor processing method of claim 1, wherein the first roughness is greater than or about 0.50 nm.

7. The semiconductor processing method of claim 1, wherein the second roughness is less than or about 0.30 nm.

8. A semiconductor processing method comprising:
forming a layer of silicon nitride on a semiconductor substrate, wherein the layer of silicon nitride is characterized by a first roughness;
transferring the semiconductor substrate to a beamline ion implantation chamber or plasma doping chamber;
performing a beamline ion implantation process or a plasma doping process on the layer of silicon nitride; and
reducing a surface roughness of the layer of silicon nitride to a second roughness less than the first roughness.

9. The semiconductor processing method of claim 8, wherein the layer of silicon nitride is formed on a layer of polysilicon.

10. The semiconductor processing method of claim 8, wherein the layer of silicon nitride is formed through plasma-enhanced chemical vapor deposition.

11. The semiconductor processing method of claim 8, wherein the layer of silicon nitride is characterized by a thickness of less than or about 100 nm.

12. The semiconductor processing method of claim 8, wherein the layer of silicon nitride is formed at a temperature of less than or about 500° C., and wherein the beamline ion implantation process or the plasma doping process is performed at a temperature of less than or about 550° C.

13. The semiconductor processing method of claim 12, wherein the beamline ion implantation process or the plasma doping process is performed at a temperature of greater than or about −100° C.

14. The semiconductor processing method of claim 8, wherein the beamline ion implantation process or the plasma doping process is performed at a temperature of less than or about 50° C.

15. The semiconductor processing method of claim 8, wherein the beamline ion implantation process or the plasma doping process is performed with helium, neon, argon, silicon, boron, carbon, nitrogen, or germanium ions.

16. The semiconductor processing method of claim 15, wherein the second roughness is less than or about 0.40 nm.

17. A semiconductor processing method comprising:
forming a layer of silicon nitride on a semiconductor substrate within a first semiconductor processing chamber, wherein the layer of silicon nitride is characterized by a first roughness, and wherein the layer of silicon nitride is formed on a layer of material;
transferring the semiconductor substrate from the first semiconductor processing chamber to an ion implantation chamber;
performing an ion implantation process on the layer of silicon nitride, wherein the ion implantation process comprises a beamline ion implantation process or a plasma doping process; and
reducing a surface roughness of the layer of silicon nitride to a second roughness less than the first roughness.

18. The semiconductor processing method of claim 17, wherein the layer of material comprises polysilicon.

19. The semiconductor processing method of claim 17, wherein the layer of silicon nitride is formed at a temperature of less than or about 550° C., and wherein the ion implantation process is performed at a temperature of greater than or about −100° C.

20. The semiconductor processing method of claim 17, wherein the first roughness is at least about 0.60 nm, and wherein the second roughness is less than or about 0.50 nm.
